(19) United States
(12) Patent Application Publication
(10) Pub. No.: US 2007/0011537 A1
(43) Pub. Date: Jan. 11, 2007

(54) Systems and methods for self-diagnosing LBIST

(75) Inventor: Naoki Kiryu, Tokyo (JP)

Correspondence Address: LAW OFFICES OF MARK L. BERRIER, 3811 BEE CAVES ROAD, SUITE 204, AUSTIN, TX, 78746, US

(73) Assignee: Toshiba America Electronic Components

(21) Appl. No.: 11/158,601

(22) Filed: Jun. 22, 2005

(51) Int. Cl. G01R 31/28

(52) U.S. Cl. 714/733

(57) ABSTRACT

Systems and methods for performing logic built-in self-tests (LBISTs) in digital circuits. In one embodiment, a system has first and second target logic, each of which has LBIST circuitry incorporated therein. The system also includes comparison circuitry which is coupled to the first and second LBIST circuitry. The comparison circuitry is configured to detect differences between data generated by the LBIST circuitry of the first target logic and data generated by the LBIST circuitry of the second target logic (e.g., MISR signature values.) The comparison circuitry is also configured to provide information localizing the sources of the differences. In one embodiment, this localizing information comprises values from a test cycle counter, a scan shift counter and a set of XOR gates that compare the bits of the MISR values.

### BACKGROUND

1. Field of the Invention

The invention relates generally to the testing of electronic circuits, and more particularly to systems and methods for using logic built-in self-test (LBIST) circuitry to identify the existence of a circuit defect and provide data to localize the defect in the device under test.

2. Related art

Digital devices are becoming increasingly complex. As the complexity of these devices increases, there are more and more chances for defects that may impair or impede proper operation of the devices. The testing of these devices is therefore becoming increasingly important.

Testing of a device may be important at various stages, including in the design of the device, in the manufacturing of the device, and in the operation of the device. Testing at the design stage ensures that the design is conceptually sound. Testing during the manufacturing stage may be performed to ensure that the timing, proper operation and performance of the device are as expected. Finally, after the device is manufactured, it may be necessary to test the device at normal operating speeds to ensure that it continues to operate properly during normal usage.

One way to test for defects in a logic circuit is a deterministic approach. In a deterministic method, each possible input pattern is applied at the inputs of the logic circuit, with each possible set of state values in the circuit. The output pattern generated by each set of inputs and state values is then compared with the expected output pattern to determine whether the logic circuit operated properly. If the number of possible input patterns and number of states is large, however, the cost of deterministic testing of all the combinations is generally too high for this methodology to be practical. An alternative method of testing that has a lower cost is therefore desirable.

One alternative is a non-deterministic approach in which pseudorandom input test patterns are applied to the inputs of the logic circuit. The outputs of the logic circuit are then compared to the outputs generated in response to the same pseudorandom input test patterns by a logic circuit that is known to operate properly. If the outputs are the same, there is a high probability that the logic circuit being tested also operates properly. The more input test patterns that are applied to the logic circuits, and the more random the input test patterns, the greater the probability that the logic circuit under test will operate properly in response to any given input pattern. This non-deterministic testing approach is typically easier and less expensive to implement than a deterministic approach.

One test mechanism that can be used to implement a deterministic testing approach is a built-in self-test (BIST). This may also be referred to as a logic built-in self-test (LBIST) when applied to logic circuits. BIST and LBIST methodologies are generally considered part of a group of methodologies referred to as design-for-test (DFT) methodologies. DFT methodologies impact the actual designs of the circuits that are to be tested. LBIST methodologies in particular involve incorporating circuit components into the design of the circuit to be tested, where the additional circuit components are used for purposes of testing the operation of the circuit's logic gates.

In a typical LBIST system, LBIST circuitry within a device under test includes a plurality of scan chains interposed between levels of the functional logic of the device. Typically, pseudorandom patterns of bits are generated and stored in the scan chains. This may be referred to as scanning the data into the scan chains. After a pseudorandom bit pattern is scanned into a scan chain, the data is propagated through the functional logic to a subsequent scan chain. The data is then scanned out of the subsequent scan chain. This test cycle is typically repeated many times (e.g., 10,000 iterations,) with the results of each test cycle being combined in some manner with the results of the previous test cycles. After all of the scheduled test cycles have been completed, the final result is compared to a final result generated by a device that is known to operate properly. Based upon this comparison, it is determined whether the device under test operated properly.

This conventional configuration has some drawbacks, however. The output of the functional logic is compressed to reduce storage and bandwidth requirements. As a result, some of the information content is lost. For example, the compression can be accomplished through the use of a multiple input signature register (MISR). The captured data from all of the LBIST scan chains is combined with data already stored in the MISR to produce a new signature value in the MISR. This is repeated for each of the test cycles, and the resulting signature value is compared with the signature generated by a good chip. If the signature values match, the device under test has functioned properly. If the signature values do not match, the device under test has malfunctioned.

As pointed out above, the signature value in the MISR is generated by combining an existing signature value with data from the LBIST scan chains. Consequently, data errors that propagate to the signature value in the MISR are combined with subsequent scan chain data, so that the specific cause of each error cannot be identified. Thus, the signature value in the MISR does not contain sufficient information to localize the defect in the functional logic. The lost information can be valuable in determining the root cause of the malfunction so that the defects can be eliminated or their effect mitigated.

It would therefore be desirable to provide systems and methods to test the circuitry which are able to localize errors and thereby enable analysis of the defects that caused the errors.

### SUMMARY OF THE INVENTION

One or more of the problems outlined above may be solved by the various embodiments of the invention. Broadly speaking, the invention comprises systems and methods for performing logic built-in self-tests (LBISTs) in digital circuits. In one embodiment, the LBIST circuitry of two target circuits is initialized and executed simultaneously by the same controller. The results of the functional logic are compared at every scan cycle of the execution to detect any errors (defects). When detected, system parameters are examined and used to localize the defect in the functional logic.

The invention may be implemented in a variety of ways, and various exemplary embodiments will be described in detail below. In one embodiment, two devices to be tested are connected to a test bench, or ATE (automated test equipment). The LBIST circuitry of two target circuits is initialized with identical parameters from the ATE, and the LBIST scan chains are set with the same input patterns generated by their respective pattern generators. The ATE controller then simultaneously executes the functional logic of the two targets. The computed results, having been stored in the scan chains, are scanned into the MISR's of the target circuits, where a data signature is generated.

At each scan cycle, the two MISR signatures are examined by comparison circuitry in the ATE. The corresponding signature bits are XOR'd and then OR'd to determine if any of the bits are different. If no differences are detected, the ATE controller continues processing until all of the computed bits for that test cycle are examined. The next set of input data is then processed and examined until all of the required test patterns are processed successfully. If, at any point, there are differences, the unloading of the scan chains is halted and the data provided by the XOR gate is stored and examined to determine which scan chains are involved. The ATE also tracks and stores the scan cycle and test cycle numbers. The scan cycle number is used to determine which scan chain latches are involved. This localizes defect to a small part of the functional logic. The test cycle number is used to determine the inputs to the pattern generator(s) so that the input test data can be regenerated (and the error reproduced) for further testing and analysis (in the same or other circuits).

One alternative embodiment comprises a system having first and second target logic, each of which has LBIST circuitry incorporated therein. The system also includes comparison circuitry which is coupled to the first and second LBIST circuitry. The comparison circuitry is configured to detect differences between data generated by the LBIST circuitry of the first target logic and data generated by the LBIST circuitry of the second target logic. The comparison circuitry is also configured to provide information localizing the sources of the differences.

Another alternative embodiment comprises a method including generating LBIST signatures in first and second target logic circuits, comparing the LBIST signatures, detecting differences between the LBIST signatures and, when a difference between the LBIST signatures is detected, providing information localizing the difference.

In another alternative embodiment, a similar process is followed using circuitry which does not contain MISR's. Rather, the bits scanned out of the scan chains are sent directly to the XOR gate of the ATE to be compared. In another alternative embodiment, the target logic to be compared and the circuitry used to compare the results all reside within the same device.

Numerous additional embodiments are also possible.

### BRIEF DESCRIPTION OF THE DRAWINGS

Other objects and advantages of the invention may become apparent upon reading the following detailed description and upon reference to the accompanying drawings.

FIG. 1 is a functional block diagram illustrating the principal operation of a simple STUMPS-type LBIST system in accordance with one embodiment.

FIG. 2 is a diagram illustrating the phases of operation of the LBIST system in accordance with one embodiment.

FIG. 3 is a diagram illustrating the operations within each phase in accordance with one embodiment.

FIG. 4 is a functional block diagram illustrating an LBIST architecture that can be used in conjunction with the testing of logic circuits in accordance with one embodiment.

FIG. 5 is a functional block diagram illustrating the MISR signature comparison in accordance with one embodiment.

FIG. 6 is a timing diagram illustrating register values and signals associated with one embodiment.

While the invention is subject to various modifications and alternative forms, specific embodiments thereof are shown by way of example in the drawings and the accompanying detailed description. It should be understood, however, that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF PREFERRED EMBODIMENTS

One or more embodiments of the invention are described below. It should be noted that these and any other embodiments described below are exemplary and are intended to be illustrative of the invention rather than limiting.

As described herein, various embodiments of the invention comprise systems and methods associated with logic built-in self-test (LBIST) circuitry to identify the existence of logic circuit defects and provide data to localize the defect in the devices under test.

In one embodiment, LBIST circuitry, in conjunction with automated test equipment (ATE) is used to simultaneously process input patterns through some target logic within two “identical” devices, capturing and then comparing the computed patterns. The LBIST circuitry of each of the target devices consists of a pattern generator (e.g., a pseudorandom pattern generator, PRPG), scan chains, and multiple signal input generator (MISR). Both devices are connected to the ATE and are initialized with identical parameters from the ATE. The pattern generators are then able to set the same input patterns into the LBIST scan chains of each device. The ATE controller then executes the functional logic of the two targets. That is, the input patterns are propagated through the functional logic, producing an output pattern. These computed results, having been stored in the scan chains (captured), are scanned into their respective MISR's. The MISR's generate a data signature for each target. At each scan cycle, the two MISR signatures are compared in the ATE to determine if there are any differences (by XOR'ing the corresponding signature bits and then OR'ing that result). If no differences are detected, the ATE controller continues processing until all of the scan chains bits are examined. The next set of input data is then processed through the functional logic and examined until all of the required test patterns are processed successfully. If, at any point, differences in the signatures are detected, the unloading of the scan chains is halted and the LBIST data (from the XOR gate and cycle counters) is stored and examined to determine which scan chains are involved. An error analysis is then performed. To continue the test, the MISR signatures would be resynchronized to so that additional errors would be properly identified.

The various embodiments of the invention may provide a number of advantages over conventional systems. For example, the use of a MISR to generate a data signature with the inherent loss of information is typical. The frequent examination of the signature and the availability of the test data at the point within a test at which an error occurs is not typical. Immediately after an error is incorporated into the signature, prior to further calculation, the position of the differences in the two signatures is meaningful. The position of the difference(s) within the XOR output indicates which of the scan chains was the source of the error. Further, the scan cycle and test cycle numbers are tracked and stored by the ATE when a signature difference is detected. The scan cycle number indicates which latch within the scan chain initially received the erroneous data and localizes the defect to a small part of the functional logic. The test cycle number can be used to determine the inputs to the pattern generator(s) so that the input test data can be reproduced for further testing and analysis (e.g., in the same or other circuits).

Various embodiments of the invention will be described below. Primarily, these embodiments will focus on implementations of a STUMPS-type LBIST architecture which is implemented within an integrated circuit. It should be noted that these embodiments are intended to be illustrative rather than limiting, and alternative embodiments may be implemented in BIST architectures other than the STUMPS architecture, and may also be implemented in circuits whose components are not strictly limited to logic components (e.g., AND gates, OR gates, and the like). Many such variations will be apparent to persons of ordinary skill in the art of the invention and are intended to be encompassed by the appended claims.

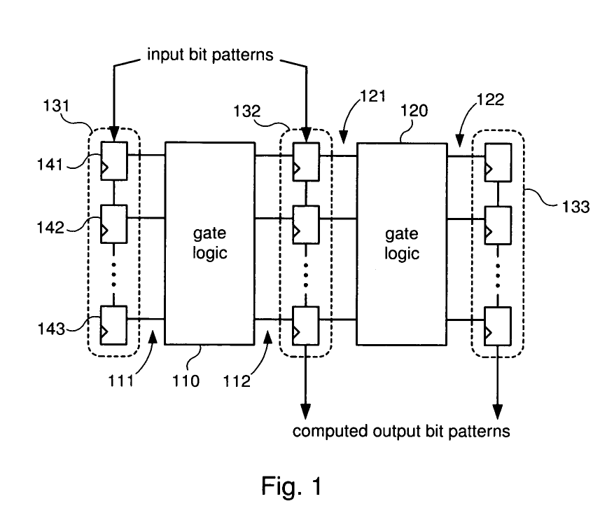

Referring to FIG. 1 a functional block diagram illustrating the principal operation of a simple STUMPS-type LBIST system is shown. The LBIST system is incorporated into an integrated circuit. In this figure, the functional logic of the integrated circuit includes a first portion 110 and a second portion 120. Functional logic 110 is, itself, a logic circuit having a plurality of inputs 111 and a plurality of outputs 112. Similarly, functional logic 120 forms a logic circuit having a plurality of inputs 121 and a plurality and outputs 122. Functional logic 110 is coupled to functional logic 120 so that, in normal operation, outputs 112 of functional logic 110 serve as inputs 121 to functional logic 120.

Each of the inputs to, and outputs from, functional logic 110 and 120 is coupled to a scan latch. The set of scan latches 131 that are coupled to inputs 111 of functional logic 110 forms one is referred to as a scan chain. The latches are serially coupled together so that bits of data can be shifted through the latches of a scan chain. For example, a bit may be scanned into latch 141, then shifted into latch 142, and so on, until it reaches latch 143. More specifically, as this bit is shifted from latch 141 into latch 142, a second bit is shifted into latch 141. As a bit is shifted out of each latch, another bit is shifted into the latch. In this manner, a series of data bits can be shifted, or scanned, into the set of latches in scan chain 131, so that each latch stores a corresponding bit. Data can likewise be scanned into the latches of scan chain 132.

Just as data can be scanned into the latches of a scan chain (e.g., 131,) data can be scanned out of the latches of a scan chain. As depicted in FIG. 1, the latches of scan chain 132 are coupled to the outputs of functional logic 110. Each of these latches can store a corresponding bit than his output by functional logic 110. After these output bits are stored in the latches of scan chain 132, the output data bits can be shifted through the series of latches and provided as an output bit stream. Data can likewise be scanned out of the latches of scan chain 133. It should be noted that the structure illustrated in FIG. 1 does not show data being scanned into scan chain 133, or data being scanned out of scan chain 131. Alternative embodiments may be configured to scan data in and out of these scan chains.

The LBIST system of FIG. 1 operates basically as follows. Pseudorandom bit patterns are generated and are scanned into the scan chains (131, 132) that are coupled to the inputs of functional logic 110 and 120. The pseudorandom bit patterns that are stored in scan chains 131 and 132 are then propagated through the corresponding functional logic. That is, the bit pattern in scan chain 131 is propagated through functional logic 110, while the bit pattern in scan chain 132 is propagated through functional logic 120. Functional logic 110 and 120 process the inputs and generate a corresponding set of outputs. These outputs are captured (stored) in the scan chains (132 and 133) that are coupled to the outputs of the functional logic. The output bit patterns stored in scan chains 132 and 133 are then scanned out of these scan chains.

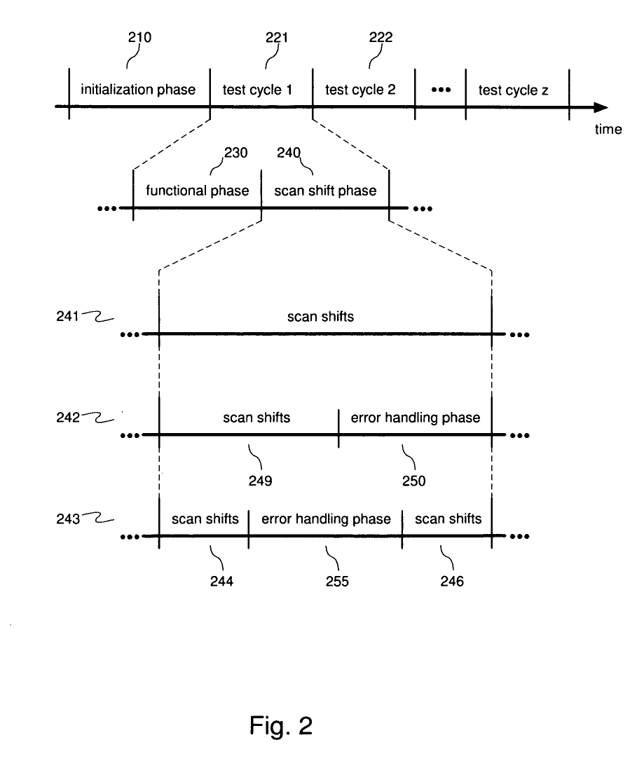

Referring to FIG. 2, a diagram illustrating the phases of operation of the LBIST system in accordance with one embodiment is shown. In this embodiment, two devices under test (one of which is known to be operating properly) are given identical inputs (input data and command signals) and are operated simultaneously. Therefore, their phases of operation are coincident. FIG. 2 shows four different phases of operation of the LBIST system. Nominally there are three phases: initialization; functional; and scan shift. The fourth phase, an error handling phase, can occur within the scan-shift phase. In initialization phase 210, the various components of the system are prepared for normal LBIST operation (i.e., execution of test cycles 221, 222.) This may include resetting various components, providing a seed for a pseudorandom number generator, setting values in registers, and so on. In functional phase 230, data is propagated through the functional logic of the device in which the LBIST system is implemented. In scan shift phase 240, data is scanned into and out of the scan chains of the LBIST system and comparisons are made of output data signatures. In the error handling phase 250 (or 255), the operation of various components of the LBIST system is (temporarily) suspended in order to enable analysis of data within the system.

As a shown in the figure, operation of the LBIST system begins with initialization phase 210. As noted above, the various components of the system are prepared for normal operation during this phase. It may be necessary to ensure that several registers (e.g., test loop counter register, scan shift counter register, bit monitor register) have the appropriate values stored therein. Because the first test cycle (221) in the embodiment depicted in FIG. 2 begins with a functional phase (230), it is also necessary in the initialization phase to generate a first set of pseudorandom bit patterns and to load these bit patterns into the scan chains that are interposed between the functional logic of the device under test. After these operations are performed, the LBIST system is ready for operation.

Following initialization phase 210, the LBIST system begins a first test cycle 221 that includes functional phase 230 and a scan shift phase 240. Scan shift phase 240 may include only scan shifts as shown in exemplary phase 241, or it may possibly include error handling phases (e.g., 250 or 255, as shown in exemplary scan shift phases 242 and 243.) If the examination of the MISR signature or other data indicates that the functional logic of the device under test operated properly during the first test cycle 221, the system proceeds to a second test cycle 222 (again beginning with a functional phase) and so on, to fulfill the requisite test termination conditions (e.g., completion of a predetermined number of test cycles.) At the end of a functional phase, the resulting captured data is scanned out of the scan chains and examined (during the subsequent scan shift phase). During a scan shift phase of a test cycle, data that is scanned out of the scan chains is examined to determine if an error occurred and, if necessary, the LBIST testing may be suspended, or halted, to enable diagnosis of malfunctions using the available data (in an error handling phase). The test cycles can be repeated a predetermined number of times and then automatically halted if no errors are detected.

During functional phase 230, the data that was scanned into the scan chains is propagated through the functional logic of the device(s) under test. At the end of this functional phase, the output of the functional logic is captured by the scan chains. As noted above, a scan chain that is positioned between successive functional logic blocks serves to both provide inputs to one of the functional logic blocks and capture the outputs of the other of the functional logic blocks. The data that is captured in the scan chains at the end of the functional phase is scanned out of the scan chains during scan shift phase 240. At the same time the captured data is scanned out of the scan chains, new pseudorandom bit patterns are scanned into the scan chains to prepare for the functional phase of the next test cycle.

In one embodiment, as the captured data is scanned out of the scan chains, it is provided to a multiple input signature register (MISR) of the respective device and the signature contained in the MISR is updated using this data. The signatures in the MISR's of both devices are then compared. If the signatures match, the devices under test are assumed to be operating properly, and the system proceeds to the next scan cycle within the current scan shift phase. If the signatures do not match, one device under test has malfunctioned, and the system enters an error handling phase. During the error handling phase 250 (or 255) of the scan shift phase 242 (or 243), the scan shift operations 249 (or 244) of the LBIST system are halted (or temporarily suspended). While these operations are suspended, the state of the system is maintained, so that the system can be examined and the scan shift operations 246 can be resumed after the error handling phase 255 without having to re-initialize the system (except that the MISR signature would be reset). During the error handling phase 250 (or 255), the data that was captured in various registers and the scan chains can be processed and examined to determine which the functional logic blocks malfunctioned.

If the examination of the MISR (or other captured data) indicates that a malfunction has occurred in the devices under test, diagnosis of the malfunction may proceed using the captured data, MISR data, or other data that may be available within the LBIST system. The specific means for analyzing the data will not be discussed here, as they are beyond the scope of the present disclosure. It should be noted, however, that, because the operation of the present LBIST system can be suspended or halted upon the occurrence of a malfunction, the system contains data that can be useful in the diagnosis of the malfunction. As pointed out above, this type of data is not available in conventional LBIST systems because the erroneous data resulting directly from the malfunction is combined with subsequent data, so that the original error is obscured.

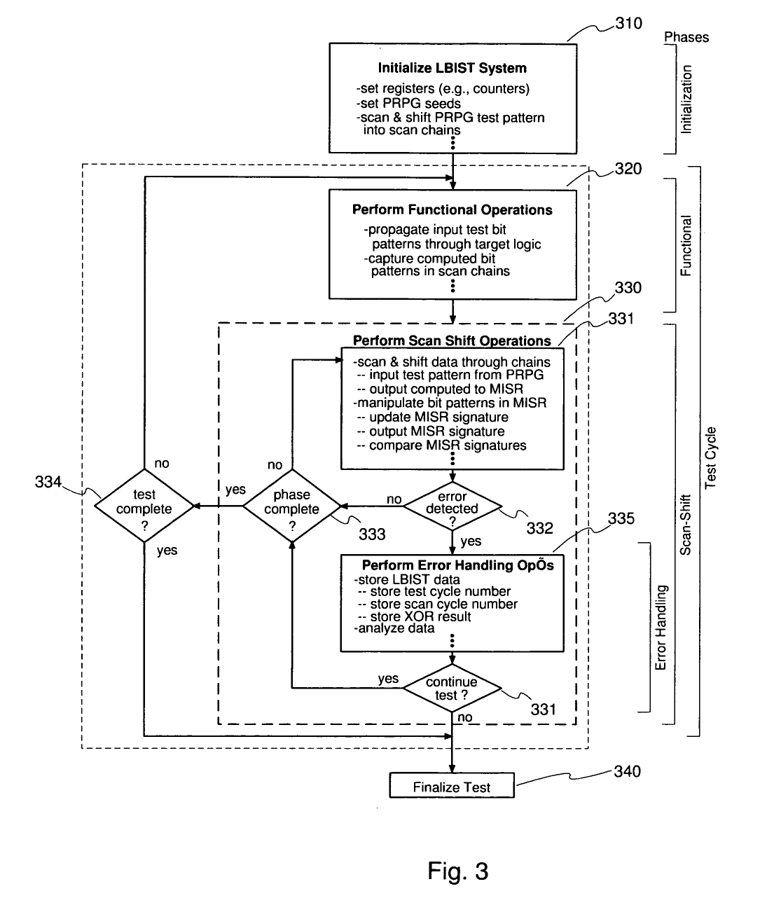

The operation of the LBIST system is summarized in FIG. 3. This figure is a flow diagram illustrating the initialization of the system and the repeating test cycles that are performed. Also illustrated are the major decision points for each test cycle and the subsequent actions taken based upon these decisions.

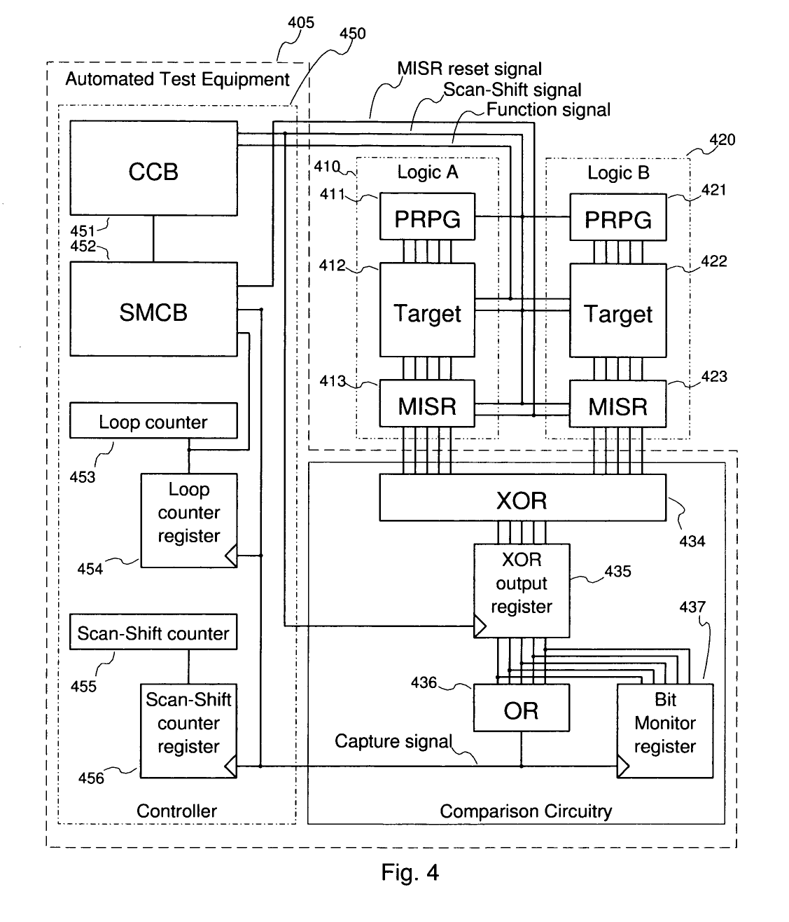

Referring to FIG. 3, operation of the system begins with the initialization of the LBIST components (block 310.) After the system is initialized, it then executes a functional phase, including propagating data from the scan chains through the functional logic and capturing the resulting bit patterns in the scan chains (block 320.) Next, the system executes the scan shift phase (block 330), in which each of the bits of the captured bit patterns are scanned out of the scan chains while new bits of a pseudorandom bit pattern are scanned into the scan chains. The bits that are scanned out of the scan chains are used to update the MISR signature bits which are then immediately compared with a second MISR signature's bits (block 331.) If a difference (error) is detected in the signatures (332), the system enters an error handling phase in which the functional and scan shift operations of the system are suspended (block 335.) During the error handling phase, the individual signature bit comparisons from the XOR gate are available for analysis. Also available are other registers such as the scan shift counter and test cycle counter. (See FIG. 4.) The system also determines whether execution of the LBIST testing will continue (336 to 333), or be halted (336 to 340). If it is determined that the testing will continue, the system either executes another scan shift cycle (333 to 331), enters a new test cycle (333 to 334 to 320), or the testing halts because testing is complete (333 to 334 to 340). If there are scan shift cycles remaining in the current scan shift phase, execution continues through the scan shift phase. If there are no scan shift cycles remaining and there are test cycles remaining to be executed, a new test cycle is started. This test cycle also consists of a functional phase (block 320,) a scan shift phase (block 330, 331) and, if an error is detected, an error handling phase (block 335). This continues until the testing is halted. The testing will halt when all test cycles are complete or it is determined that the testing should terminate because of an error.

In one embodiment, the LBIST system is implemented as shown in the functional block diagram of FIG. 4. As depicted, the STUMPS architecture comprises LBIST controller 450 (including SMCB 452, CCB 451, counters 453 and 455), PRPG's 411 and 421, a set of scan chains interspersed in target logic 412 and 422, MISR's 413 and 423, comparison logic 430 (XOR 434, OR 436) and various counters and registers (test loop counter and register 453 and 454, scan-shift counter and register 455 and 456, XOR and bit monitor registers 435 and 437). These LBIST components may, in different embodiments, be part of the ATE or they may be integrated with logic circuits 410 and 420, which the LBIST components are designed to test. It should be noted that, while only four connections to the scan chains are depicted in FIG. 1, there may be many scan chains in the LBIST design. Also, all or some of the components may reside on-chip with the target logic.

LBIST controller 450 includes control circuitry that controls the operation of the remainder of the LBIST components. For purposes of clarity, the structure of LBIST controller 450 is simplified in the figure. For example, LBIST controller 450 is depicted as having only two major components (CCB and SMCB) and providing function and scan-shift signals to only some of the other LBIST components within Logic A 410, Logic B 420 and comparison circuitry 430. The controller typically has additional connections and is coupled directly to each of the LBIST components. LBIST controller 450 also performs functions that are not illustrated or described in detail, such as providing seed values to PRPG 411 and PRPG 421 which are used by the PRPG's to generate pseudorandom sequences of bits.

The purpose PRPG 411 (and PRPG 421) is to generate pseudorandom sequences of bits. A PRPG can, for example, be implemented as a linear feedback shift register (LFSR). The pseudorandom sequence of bits generated by PRPG 411 (and 421) is to provide a set of input bits to be propagated through the functional logic components of logic circuit 412 (and 422). The pseudorandom sequences are therefore provided to each of the scan chains interspersed within the target logic. It should be noted that other components may be incorporated at this stage. For instance, the pseudorandom bit sequences can be processed by a phase shifter prior to being loaded into the scan chains.

The pseudorandom bit patterns that are generated by PRPG 410 (and 411) are loaded into the scan chains. Each of the scan chains comprises a series of scan latches that are configured to alternately shift data (the pseudorandom bit patterns or functional logic output) through the scan chains or to hold data that has been propagated through the functional logic. Each of the scan chains is positioned before or after (interposed with) respective portions of target logic circuitry 412 (and 422). Thus, for each portion of logic circuit 412 (and 422), there is a scan chain which precedes this portion and provides inputs to the corresponding logic, as well as a scan chain which follows this portion and receives the output of the corresponding logic.

After the pseudorandom bit patterns have been allowed to propagate through the functional components of target logic circuit 412 (and 422) and the results have been captured in the scan chains, the contents of the scan chains are scanned out of the scan chains (i.e., they are unloaded from the scan chains) to MISR 413 (and 423). In alternative embodiments, more complex circuitry may allow the number of bits passed to the MISR to be reduced, thereby reducing the size of the MISR. This would, however, obfuscate errors and hinder the analysis of those errors.

The bits from scan chains within 412 (and 422) are provided to MISR 413 (and 423). The MISR provides a means to observe the resulting data bits and to compare this information. For example, the signature value in MISR 413 in a first device could be compared with the signature value in MISR 423 of a second device. Typically, MISR 412 (and 422) generates a cumulative value that is based upon the output of the scan chains at each cycle. For example, in one embodiment, MISR 412 (and 422) performs a modulo operation on the output of the scan chains. That is, the MISR divides the current value stored in MISR by the output of the scan chains, and retains the remainder from this computation. This computation is performed, and the value stored in the MISR is updated, during each scan cycle. The cumulative value stored in the MISR (the signature) is then examined after some number of scan cycles. Here, the MISR signature is examined each time it is updated (i.e., after each scan cycle,) as each time it is updated, the new signature may include an error.

The data stored in MISR 413 (or 423) can be read out of the device, for instance, via a JTAG port of the device into which the LBIST components are incorporated. (“JTAG” stands for Joint Test Action Group, which is the group that developed this particular type of boundary scan port.) The may also have dedicated output ports. These allow the values stored in MISR 413 to be compared to a second value from MISR 423. If, for example, target logic 422 is presumed to operate properly and the signature values do not match, then one or more of the operations performed by the functional components of logic circuit 412 must have failed, thereby providing an incorrect data bit in the output scan chain, which then propagated to MISR 413 and resulted in a signature which is different from that in MISR 423.

The operation of LBIST components within 410, 420 and 430 is controlled by LBIST controller 450, which generates the control signals necessary to execute the phases of operation depicted in FIG. 2 (i.e., the initialization, function, scan shift and error handling phases.) The generation of these control signals is performed in this embodiment by clock control block 451, operating in conjunction with state machine control block 452. In one embodiment, LBIST controller 450 is configured to generate control signals by selectively gating a clock signal generated by a PLL. A test loop counter (453) and scan-shift counter (455) track the number of test cycles and the number of scan-shifts within each test cycle, respectively. The counter registers (454 and 456) capture the counter values in the event an error is detected. This information, in conjunction with the information in bit monitor register 437, provides data used to localize defects in the target functional logic.

It should be noted that while the embodiment depicted in FIG. 4 compares LBIST data generated by a first device under test with corresponding data generated by a second (good) device, alternative embodiments may determine the existence of errors in other ways. For example, one alternative embodiment determines whether the data contains errors by comparing it to stored data previously generated by a good device. This data can be retrieved from memory and compared to the data of the device under test in the same way that data of the second (good) device is compared. Because of the very large amounts of data that would have to be stored, however, this is not believed to be as practical a solution as the comparison to (good) data that is generated in parallel with the data of the device under test. The “live” comparison also has the advantage of providing as little or as much data as is needed. For instance, the live comparison could continue to provide data for LBIST that continued for an indefinite period of time.

It should also be noted that, while the embodiment of FIG. 4 compares data generated by two different devices, alternative embodiments may not. For example, one alternative embodiment may be configured to compare data generated by two identical components within a single device (e.g., two co-processors within a multiprocessor chip.)

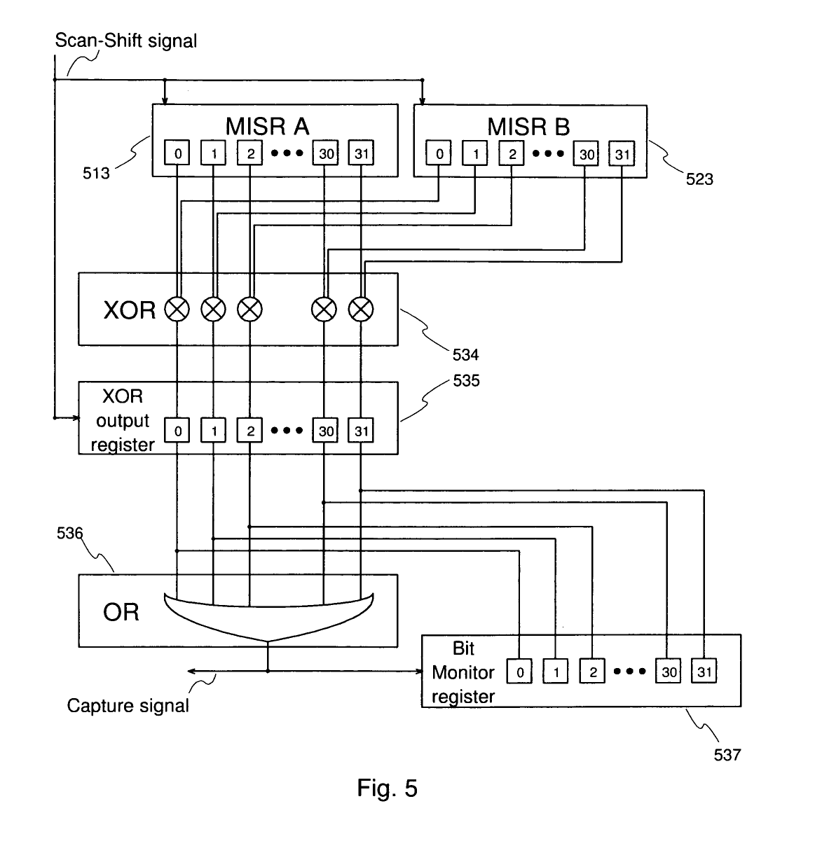

Referring to FIG. 5, a diagram illustrating the structure of the LBIST comparison logic in one embodiment is shown. At each scan cycle, signature data of a first device, generated and stored in MISR A (513) is compared with the signature data of a second, identical device (that is known to operate properly) that is generated and stored in MISR B (523). The comparison logic determines whether the signature data of the first device under test matches the signature data of the second, “good” device. The comparison is performed using XOR gate(s) 534. If the two signatures match, the bits output by XOR gate 534 are all zero, leading to a zero result at the output of OR gate 536. In such a case, the capture signal is not asserted, and LBIST testing continues. (This is equivalent to looping through the operations of block 331 in FIG. 3.) If the two signatures do not match, at least one bit of XOR 534 is nonzero and the result output by OR gate 536 is nonzero. The capture signal is therefore asserted and various connected registers are thereby caused to store relevant information (which can be used in an analysis to determine the source of the error). This information includes the output of XOR gate 534. The XOR bits from register 535 are captured in bit monitor register 537. The XOR bits identify the location(s) of the difference(s) between the two signatures. Also captured is the value of the scan shift counter, which is used to identify the scan chain latch position corresponding to the error.

It should be noted that the XOR bits from register 535 may, in an alternative embodiment, be captured in RAM instead of in a register. This could allow several cycles of failure information to be captured instead of a single one. In such an embodiment, the RAM address at which the data is stored could be incremented each time the error signal output by the OR gate is asserted.

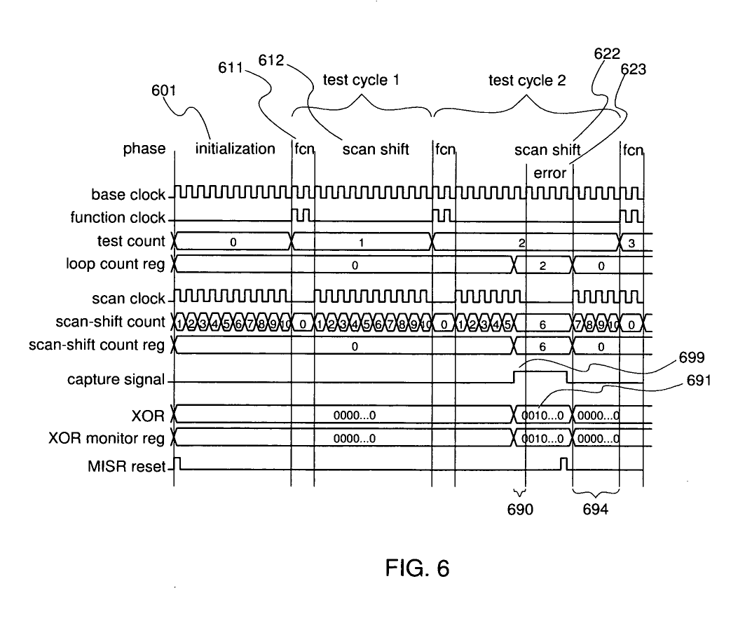

FIG. 6 is a timing diagram for an exemplary embodiment. The timing diagram spans the initialization phase and two test cycles. An error is encountered in the scan-shift phase of the second test cycle. The control signals that are illustrated include the base clock (the PLL clock signal that is gated by the LBIST circuitry), the function clock (which triggers function cycles during which data propagates through the functional circuitry), and the scan clock (which triggers scan-shift cycles during which data is scanned into and out of the scan chains).

Also shown in FIG. 6 are the test loop counter value (loop count,) the test loop register value (test loop reg,) the scan-shift counter value (scan-shift count,) the scan-shift count register (scan-shift count reg,) the value at the output of the XOR gates (XOR) and the value in the XOR bit monitor register (XOR monitor reg.) There is also a signal to indicate that an error has been encountered and to trigger suspension of scan shift operations (capture signal). When the capture signal is asserted (i.e., when an error is detected,) the values of the test cycle counter, scan-shift counter and XOR gates are stored in the test loop register, scan-shift count register and XOR bit monitor register, respectively.

FIG. 6 depicts an exemplary scenario in which an error is detected. During initialization (601,) the input test patterns are scanned into and shifted through the scan chain latches. The number of scan chain pulses is equal to the number of latches in a scan chain (10 in this example). At the beginning of the first test cycle is a functional phase 611. During this phase, input test patterns from the scan chains are propagated through the functional logic. The bits are propagated from the chains preceding the functional logic, through the logic, to the chains following the functional logic. This takes two cycles—beginning with the first clock pulse in the functional phase and ending with the second clock pulse in the functional phase. This is followed by scan-shift phase 612. As noted above, the number of scan clock signal pulses is equal to the number of scan chain latches. In this example, there are ten latches requiring ten scan-shift cycles, but other embodiments could have N latches in each scan chain, requiring N scan-shift

After each scan shift cycle, the MISR signature values are updated, and the updated values are compared by the XOR gates. If no signature differences are detected, the process continues. In the example of FIG. 6, no errors are detected in test cycle 1, but an error is detected in test cycle 2. During test cycle 2, at scan-shift number 6 (690), a difference appears in the signatures of the two MISR's and is reflected in the XOR gate output (691), which has changed from all 0's to “00100 . . . 0”. At this point during scan-shift phase 622, the capture signal is immediately asserted (699). With the assertion of the capture signal the system enters error handling phase 623. The test loop register, scan-shift count register and XOR bit monitor register capture their inputs when the capture signal is asserted. In this example, the cycle number “2” is captured in the test loop register, the number “6” is captured in the scan-shift register and “00100 . . . 0” is captured in the XOR bit monitor register. Some number of cycles is used to process and examine the LBIST data. This number of cycles may be greater than the five cycles explicitly depicted in the figure. This processing is performed so as to localize the defect in the logic. For example, since the difference was detected during scan-shift 6 in the third position of the XOR gates, the defect is in the logic whose output was captured in the sixth latch from the end of the chain corresponding to the third XOR bit. If it is useful (or necessary) to continue, the MISR signatures can be synchronized (e.g. reset) and the scan-shift phase continued, completing the remaining scan-shift cycles (e.g. 4 cycles at 694) and/or the remainder of the predetermined number of test cycles.

While the foregoing description presents several specific exemplary embodiments, there may be many variations of the described features and components in alternative embodiments. For example, the LBIST controller described above may be used to control the LBIST circuitry in both a device under test and a good device, or a separate LBIST controller may be used in conjunction with each of the devices. If separate LBIST controllers are used, it may be necessary in some embodiments to synchronize the test cycles so that the data generated in each test cycle can be properly compared. Many other variations will also be apparent to persons of skill in the art of the invention upon reading the present disclosure.

Those of skill in the art will understand that information and signals may be represented using any of a variety of different technologies and techniques. For example, data, instructions, commands, information, signals, bits, and symbols that may be referenced throughout the above description may be represented by voltages, currents, electromagnetic waves, magnetic fields or particles, optical fields or particles, or any combination thereof. The information and signals may be communicated between components of the disclosed systems using any suitable transport media, including wires, metallic traces, vias, optical fibers, and the like.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Those of skill in the art may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with application specific integrated circuits (ASICs), field programmable gate arrays (FPGAs), general purpose processors, digital signal processors (DSPs) or other logic devices, discrete gates or transistor logic, discrete hardware components, or any combination thereof designed to perform the functions described herein. A general purpose processor may be any conventional processor, controller, microcontroller, state machine or the like. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in software (program instructions) executed by a processor, or in a combination of the two. Software may reside in RAM memory, flash memory, ROM memory, EPROM memory, EEPROM memory, registers, hard disk, a removable disk, a CD-ROM, or any other form of storage medium known in the art. Such a storage medium containing program instructions that embody one of the present methods is itself an alternative embodiment of the invention. One exemplary storage medium may be coupled to a processor, such that the processor can read information from, and write information to, the storage medium. In the alternative, the storage medium may be integral to the processor. The processor and the storage medium may reside, for example, in an ASIC. The ASIC may reside in a user terminal. The processor and the storage medium may alternatively reside as discrete components in a user terminal or other device.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

What is claimed is:

1. A system comprising:
first target logic having first LBIST circuitry incorporated therein;
second target logic having second LBIST circuitry incorporated therein; and
comparison circuitry coupled to the first and second LBIST circuitry;
wherein the comparison circuitry is configured to
detect one or more differences between data generated by the first LBIST circuitry and data generated by the second LBIST circuitry, and
provide information localizing one or more sources of the one or more differences.

2. The system of claim 1, further comprising one or more registers configured to store data identifying the one or more sources of the one or more differences.

3. The system of claim 2, wherein the one or more registers include a test cycle counter register, a scan shift counter register and an XOR bit monitor register.

4. The system of claim 1, wherein the comparison circuitry comprises a plurality of XOR gates configured to XOR each bit of a MISR value generated in the first LBIST circuitry with a corresponding bit of a MISR value generated in the second LBIST circuitry.

5. The system of claim 4, further comprising an OR gate configured to receive an output value from each of the XOR gates and to produce a signal indicating whether any of the XOR output values is asserted.

6. The system of claim 1, wherein the first target logic and the second target logic comprise separate devices under test.

7. The system of claim 1, wherein the first target logic and the second target logic comprise identical components within a single device under test.

8. The system of claim 1, wherein the LBIST circuitry is configured to store the information localizing the one or more sources of the one or more differences and terminate LBIST testing upon detecting an error.

9. The system of claim 1, wherein the LBIST circuitry is configured to: store the information localizing the one or more sources of the one or more differences and temporarily suspend LBIST testing upon detecting an error; and subsequently resume LBIST testing.

10. The system of claim 9, wherein the comparison circuitry comprises a plurality of XOR gates configured to XOR each bit of a value generated in a first MISR in the first LBIST circuitry with a corresponding bit of a value generated in a second MISRT in the second LBIST circuitry, and wherein the comparison circuitry is configured to reset the first and second MISR's to a common value before resuming LBIST testing.

11. A method for LBIST testing comprising:
generating a first LBIST signature in a first target logic;
generating a second LBIST signature in a second target;
comparing the first and second LBIST signatures;
detecting a difference between the first LBIST signature and the second LBIST signature; and
when the difference between the first LBIST signature and the second LBIST signature is detected, providing information localizing the difference.

12. The method of claim 11, further comprising storing the information localizing the difference in one or more registers.

13. The method of claim 12, wherein the one or more registers include a test cycle counter register, a scan shift counter register and an XOR bit monitor register.

14. The method of claim 11, wherein detecting the difference between the first LBIST signature and the second LBIST signature comprises XOR'ing each bit of the first LBIST signature with a corresponding bit of the second LBIST signature.

15. The method of claim 14, further comprising an OR'ing the XOR'ed bits of the first and second LBIST signatures.

16. The method of claim 11, further comprising generating the first LBIST signature in a first device under test and generating the second LBIST signature in a second device under test.

17. The method of claim 11, further comprising generating the first LBIST signature in a first component of a device under test and generating the second LBI$T signature in a second component of the device under test.

18. The method of claim 11, further comprising, upon detecting the difference between the first LBIST signature and the second LBIST signature, storing the information localizing the difference and terminating LBIST testing.

19. The method of claim 11, further comprising, upon detecting the difference between the first LBIST signature and the second LBIST signature, storing the information localizing the difference, temporarily suspending LBIST testing, and subsequently resuming LBIST testing.

20. The method of claim 19, wherein generating the first LBIST signature comprises generating a first MISR signature in a first MISR and wherein generating the second LBIST signature comprises generating a second MISR signature in a second MISR, the method further comprising resetting the first and second MISR's to a common value before resuming LBIST testing.
